(19) United States
(12) Patent Application Publication
(10) Pub. No.: US 2010/0295163 A1
(43) Pub. Date: Nov. 25, 2010

(54) STACKED SEMICONDUCTOR PACKAGE ASSEMBLY

(75) Inventor: Ching-Yao Fu, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/693,502

(22) Filed: Jan. 26, 2010

(30) Foreign Application Priority Data
May 19, 2009 (CN) 200910107489.1

(51) Int. Cl. H01L 25/04

(52) U.S. Cl. 257/686; 257/E25.006

(57) ABSTRACT

A stacked package assembly includes N (where N≧2) package bodies stacked together. Each package body is made up of a substrate which comprises a top surface and a bottom surface, and a chip packaged in the substrate. The top surface of the substrate of each package body includes (N−1) pads, and the bottom surface includes N pads. The Kth pad on the top surface of the substrate of each package body is electrically connected to the (K+1)th pad on the bottom surface thereof. The Kth (K=1, 2, . . . , (N−1)) pad on the top surface of the substrate of one lower package body corresponds to the Kth pad on the bottom surface of the substrate of another upper package body stacked above the lower package body.

### BACKGROUND

1. Technical Field

The disclosure relates to package assemblies, and particularly, to stackable package assemblies.

2. Description of Related Art

Miniaturization of electronic technology creates smaller electronic devices, sometimes forcing integrated circuits (ICs) applied in such electronic devices to adapt to multifunctional roles, causing stacked packages assemblies.

FIG. 8 is a cross-sectional view of a commonly-used stacked package assembly 10, and FIG. 9 illustrates a control circuit of the assembly 10 of FIG. 8. The assembly 10 comprises a first package body 11, a second package body 12, and a third package body 13 stacked one by one and controlled by a controller 20. Each package body 11, 12, 13 comprises a substrate 15, and a chip 16 packaged in the substrate 15. Each of the substrates 15 comprises a top surface 151 comprising three upper pads A1, A2, A3 and a bottom surface 152 comprising three lower pads B1, B2, B3. The three upper pads A1, A2, A3 on the top surface 151 correspond to the three lower pads B1, B2, B3 on the bottom surface 152, respectively, and electrically connect correspondingly. When the three package bodies 11, 12, 13 are stacked one by one, the three upper pads A1, A2, A3 of the substrate 15 of one of the package bodies 11, 12, 13 are connected with the three lower pads B1, B2, B3 of another one of the package bodies 11, 12, 13 by solder balls 17, respectively.

The controller 20 comprises three control pins 21, 22, 23 to control the three chips 16 of the package assembly 10, where the three control pins 21, 22, 23 of the controller 20 are connected to the three lower pads B1, B2, B3 of the third package body 13, respectively, to control the three chips 16 of the three package bodies 11, 12, 13, respectively. In detail, a control port of the chip 16 on the first package body 11 is connected to the controller 20 by way of a first lower pad B1 of the first package body 11. A control port of the chip 16 on the second package body 12 is connected to the controller 20 by way of a second lower pad B2 of the second package body 12, and a control port of the chip 16 on the third package body 13 is connected to the controller 20 by way of a third lower pad B3 of the third package body 13. That is, structures of the three package bodies 11, 12, 13 are different from each other. Furthermore, stacked positions of each of the three package bodies 11, 12, 13 must be fixed for the chips 16 in different package bodies to correctly connect to the controller 20. Currently, the process involved together with mass production implications, is an inconvenience worth addressing.

### BRIEF DESCRIPTION OF THE DRAWINGS

FIG. 1 is a cross-sectional view of a first direction of a stacked package assembly of the disclosure.

FIG. 2 is a cross-sectional view of a second direction perpendicular to the first direction of the stacked package assembly of FIG. 1 and a control circuit of the stacked package assembly of FIG. 1.

FIG. 3 is a cross-sectional view of the first direction of one of the plurality of package bodies of the stacked package assembly of FIG. 1.

FIG. 4 is a cross-sectional view of the second direction of one of the plurality of the package bodies of FIG. 3.

FIG. 5 is a cross-sectional view of the first direction of a stacked package assembly in accordance with an exemplary embodiment of the disclosure, wherein the stacked package assembly comprises three package bodies.

FIG. 6 is a cross-sectional view of the second direction of the stacked package assembly of FIG. 5.

FIG. 7 is a schematic diagram of a controller controlling the three chips of the stacked package assembly of FIG. 5.

FIG. 8 is a cross-sectional view of a commonly used stacked package assembly.

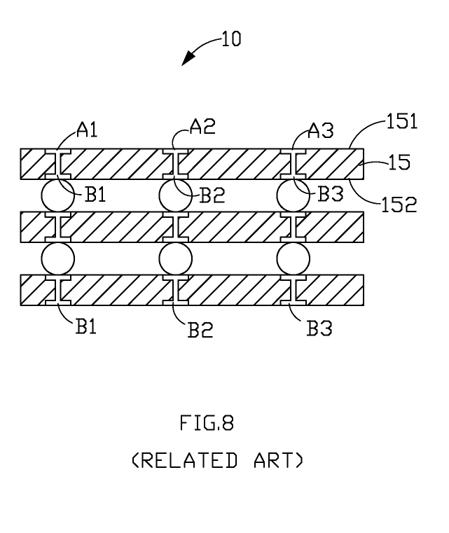

FIG. 9 is a control circuit of the stacked package assembly of FIG. 8.

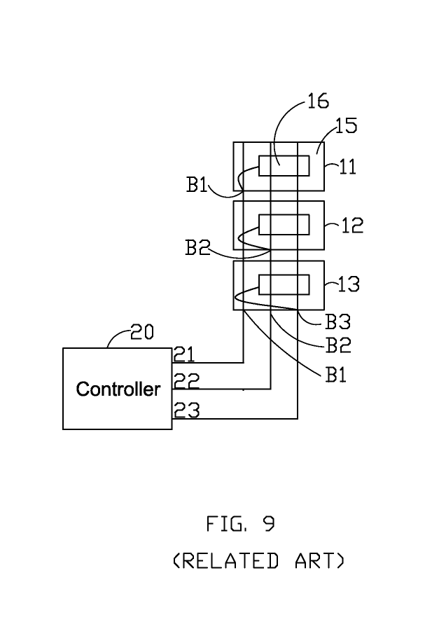

### DETAILED DESCRIPTION

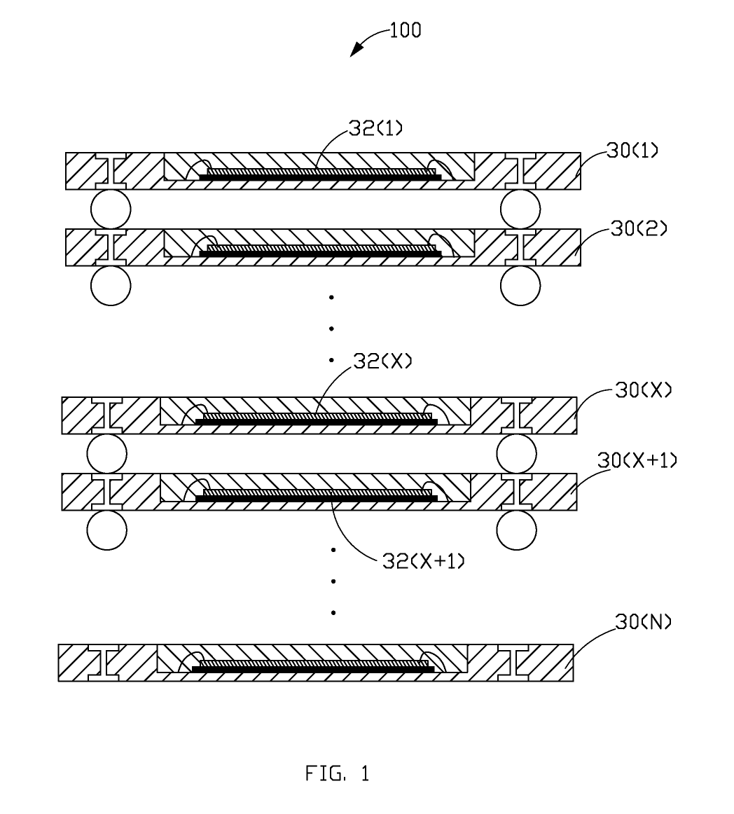

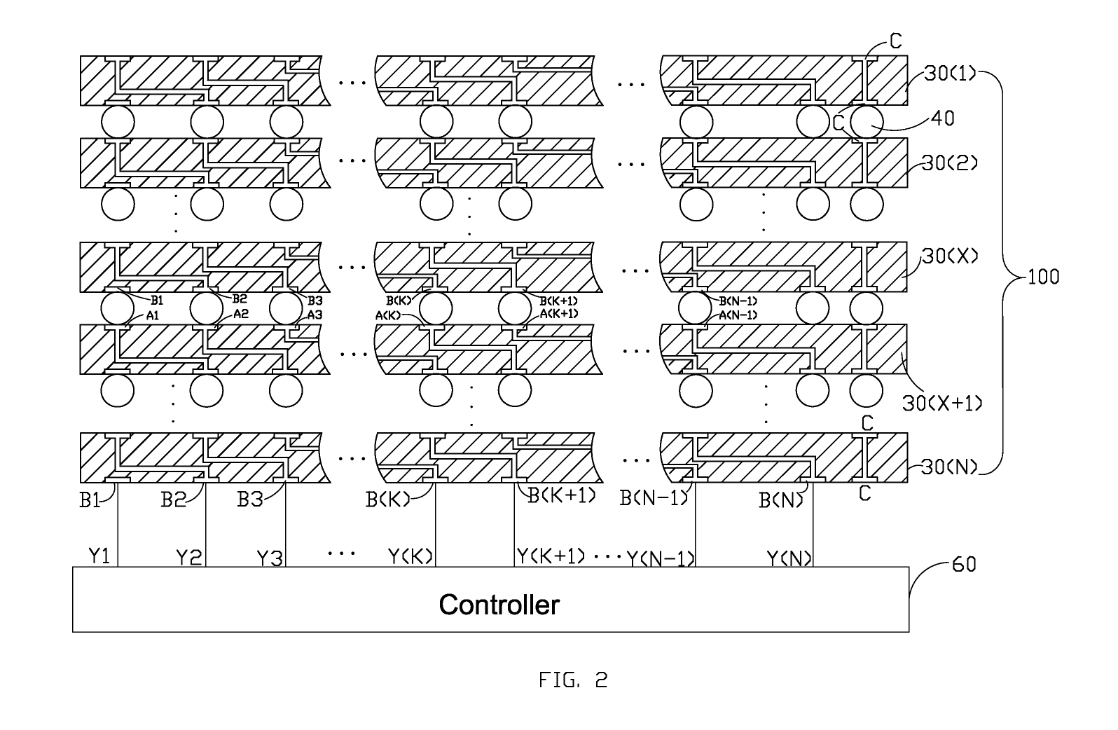

FIG. 1 is a cross-sectional view of a first direction of a stacked package assembly 100 of the disclosure, and FIG. 2 illustrates a cross-sectional view of a second direction perpendicular to the first direction of the assembly 100 of FIG. 1 and a control circuit of the assembly 100 of FIG. 1. The assembly 100 comprises a plurality of package bodies 30, herein respectively marked: 30(1), 30(2), . . . , 30(X), 30(X+1), . . . , 30(N) (where N≧2), stacked together.

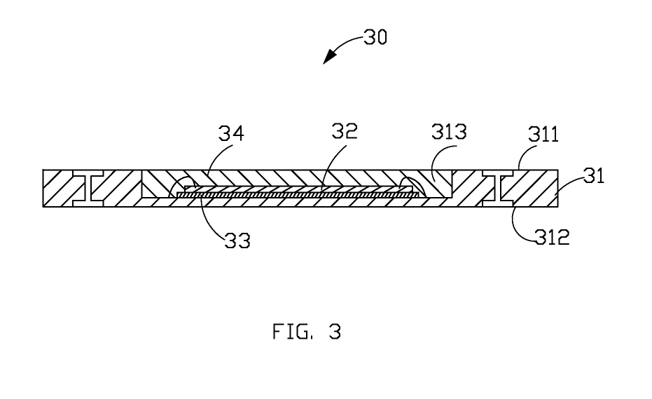

FIG. 3 is a cross-sectional view of the first direction of one of the package bodies 30 of the disclosure. Each package body 30 comprises a substrate 31 and a chip 32 packaged in the substrate 31. The substrate 31 comprises a top surface 311 and a bottom surface 312 opposite to the top surface 311. The top surface 311 of the substrate 31 comprises a groove 313 to receive the chip 32. The chip 32 is fixed in the groove 313 by adhesive 33 and sealing compound 34.

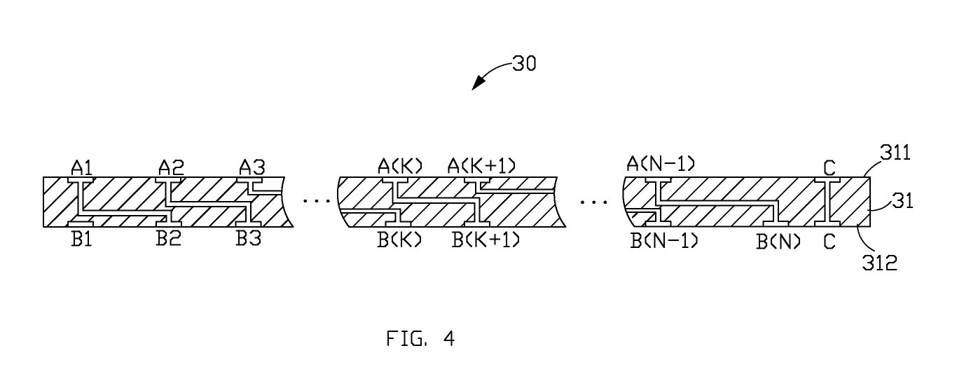

FIG. 4 is a cross-sectional view of the second direction of one of the package bodies 30 of FIG. 3. The top surface 311 of the substrate 31 of the package body 30 is configured with a plurality of upper pads A1, A2, . . . , A(K), A(K+1), . . . , A(N−1) (where N≧2), the bottom surface 312 of the substrate 31 of the package body 30 is configured with a plurality of lower pads B1, B2, . . . , B(K), B(K+1), . . . , B(N) (where N≧2). In the embodiment, there are as many or more than lower pads for each package body 30 as there are package bodies 30. The Kth (K=(1, 2, . . . , N−1)) upper pad A(K) on the top surface 311 of the substrate 31 is opposite to the Kth lower pad B(K) on the bottom surface 312. The Kth upper pad A(K) on the top surface 311 of the substrate 31 of the package body 30 is electrically connected to the (K+1)th lower pad B(K+1) on the bottom surface 312. In the illustrated embodiment, a control port of the chip 32 of each package body 30 is configured to electrically connect to a first lower pad B1 on the bottom surface 312.

Alternatively, the substrate 31 of each package body 30 is further configured with a pair of connection pads C located oppositely on the top surface 311 and the bottom surface 312 of the substrate 31, to electrically connect the package bodies 30 in series.

Referring to FIG. 2, when the package bodies 30 are stacked one by one, the connection pads C of one package body 30 are connected with that of another package body 30 by solder balls 40. The Kth (K=1, 2, . . . , N−1) pad B(K) on the bottom surface 312(X) of a upper substrate 31(X) is correspondingly soldered to the Kth pad A(K) on the top surface 311(X+1) of a lower substrate 31(X+1) of any two adjacent substrates 31(X) and 31(X+1).

A controller 60 comprises a plurality of control pins Y1, Y2, . . . , Y(K), Y(K+1), . . . , Y(N) (where N≧2) connected to the plurality of lower pads B1, B2, . . . , B(K), B(K+1), . . . , B(N) (where N≧2) of the Nth package body 30(N), respectively, to control the N chips 32 of the assembly 100. In the embodiment, the quantity of the control pins of the controller 60 is greater than or equal to that of the lower pads of each package body 30.

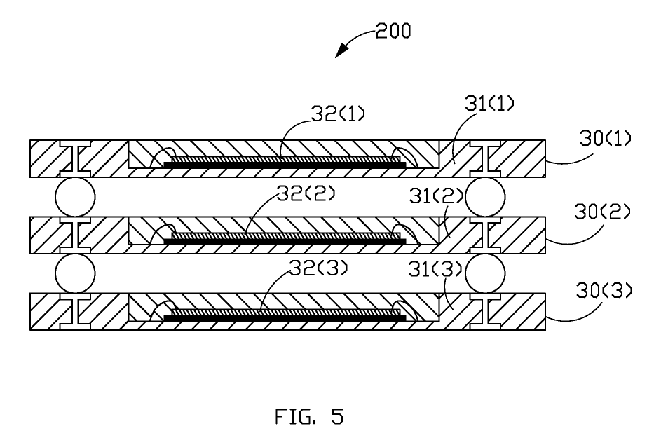

FIG. 5 is a cross-sectional view of the first direction of a stacked package assembly 200 in accordance with an exemplary embodiment of the disclosure. In the illustrated embodiment, only three package bodies 30, such as a first package body 30(1), a second package body 30(2), and a third package body 30(3), stacked one by one are shown for simplification and convenience of description. Each of the three package bodies 30 comprises the substrate 31 and the chip 32 packaged in the substrate 31.

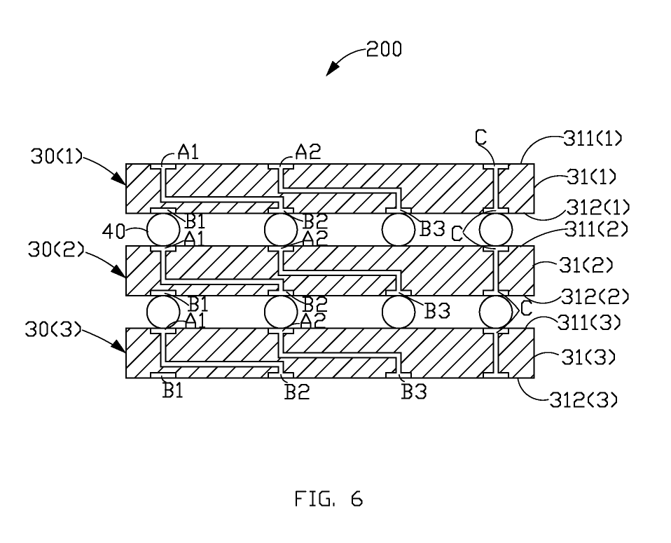

FIG. 6 is a cross-sectional view of the second direction of the assembly 200 of FIG. 5. Each of the substrates 31(1), 31(2), 31(3) of the assembly 200 is configured with two upper pads, labeled as a first upper pad A1 and a second upper pad A2, on the top surface 311, and three lower pads, labeled as a first lower pad B1, a second lower pad B2, and a third lower pad B3, on the bottom surface 312. The first upper pad A1 and the second upper pad A2 on the top surface 311 correspond to the first lower pad B1 and the second lower pad B2 on the bottom surface 312, respectively. The first upper pad A1 and the second upper pad A2 on the top surface 311 are electrically connected to the second lower pad B2 and the third lower pad B3 on the bottom surface 312, respectively. To further illustrate, a control port of the chip 32 of each package body 30 is mechanically and electrically connected to the first lower pad B1 on the bottom surface 312.

In assembly, the first package body 30(1), the second package body 30(2) and the third package body 30(3) are stacked one by one. The first lower pad B1 and the second lower pad B2 of the first package body 30(1) correspond to the first upper pad A1 and the second upper pad A2 of the second package body 30(2), respectively, and are electrically connected with each other by the solder balls 40. The first lower pad B1 and the second lower pad B2 of the second package body 30(2) correspond to the first upper pad A1 and the second upper pad A2 of the third package body 30(3), respectively, and are electrically connected to each other by the solder balls 40. In detail, the second lower pad B2 of the third package body 30(3) is connected to the first lower pad B1 of the second package body 30(2), and the third lower pad B3 of the third package body 30(3) is connected to the first lower pad B1 of the first package body 30(1).

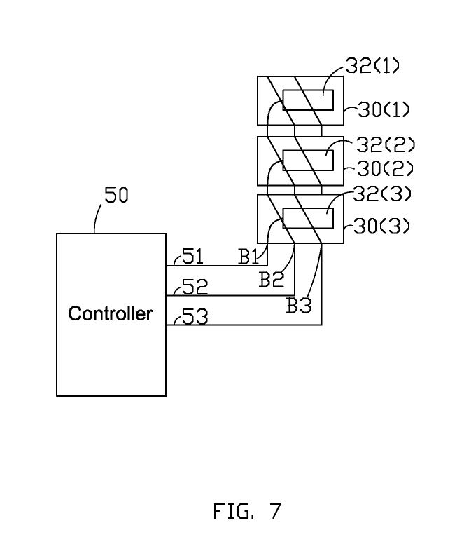

FIG. 7 illustrates a control circuit of the assembly 200 of FIG. 5. The three package bodies 30 of the assembly 200 are controlled by a controller 50. In the embodiment, the controller 50 comprises three control pins, such as a first control pin 51, a second control pin 52 and a third control pin 53 to control the three chips 32 of the assembly 200. The three control pins 51, 52, 53 of the controller 50 are connected to the three lower pads B1, B2, B3 of the third package body 30(3) to control the three chips 31 of the three package bodies 30(1), 30(2), 30(3), respectively. In detail, the control port of the chip 32 of the first package body 30(1) is connected to the controller 50 by way of the first lower pad B1 on the bottom surface 312 of the first package body 30(1), the control port of the chip 32 of the second package body 30(2) is connected to the controller 50 by way of the first lower pad B1 on the bottom surface 312 of the second package body 30(1), and the control port of the chip 32 of the third package body 30(3) is connected to the controller 50 by way of the first lower pad B1 on the bottom surface 312 of the third package body 30(3). That is, structures of the three package bodies 30(1), 30(2), 30(3) are same, so that stacking positions and orders of the three package bodies 30(1), 30(2), 30(3) can easily be altered, and that simplifies the manufacturing process, with positive production cost implications.

It is believed that the exemplary embodiments and their advantages will be understood from the foregoing description, and it will be apparent that various changes may be made thereto without departing from the spirit and scope of the or sacrificing all of its material advantages, the examples hereinbefore described merely being preferred or exemplary embodiments of the disclosure.

What is claimed is:

1. A stacked package assembly, comprising:
N (where N≧2) package bodies stacked together, each package body comprising a substrate comprising a top surface and a bottom surface, and a chip packaged in the substrate, the top surface of the substrate of each package body comprising (N−1) pads, and the bottom surface comprising N pads, wherein the Kth pad on the top surface of the substrate of each package body is electrically connected to the (K+1)th pad on the bottom surface thereof;
wherein the Kth (K=1, 2, . . . , (N−1)) pad on the top surface of the substrate of one lower package body corresponds to the Kth pad on the bottom surface of the substrate of another upper package body stacked above the lower package body.

2. The stacked package assembly of claim 1, wherein each chip packaged in each package body comprises a control port that is electrically connected to a first pad on the bottom surface of the substrate of corresponding package body.

3. The stacked package assembly of claim 1, wherein when a controller comprising N control pins controls the N chips of the N package bodies, the N control pins of the controller are connected to the N pads on a bottom surface of a substrate of the Nth package body of the N package bodies, respectively.

4. The stacked package assembly of claim 1, wherein the substrate of each package body further comprises a pair of connection pads located oppositely on the top surface and the bottom surface of the substrate of each of the N package bodies, respectively, to electrically connect the N package bodies in series.

5. The stacked package assembly of claim 1, wherein the top surface of the substrate of each of the N package bodies comprises a groove to receive the chip of each of the N package bodies.
